(19) United States
(12) Patent Application Publication
(10) Pub. No.: US 2023/0307303 A1
(43) Pub. Date: Sep. 28, 2023

(54) SEMICONDUCTOR DEVICE AND ELECTRONIC DEVICE

(71) Applicant: Murata Manufacturing Co., Ltd., Nagaokakyo-shi (JP)

(72) Inventors: Kaoru KISHIGUI, Nagaokakyo-shi (JP); Yoshihiro YOSHIDA, Nagaokakyo-shi (JP)

(21) Appl. No.: 18/205,583

(22) Filed: Jun. 5, 2023

Related U.S. Application Data
(63) Continuation of application No. PCT/JP2021/035901, filed on Sep. 29, 2021.

(30) Foreign Application Priority Data
Dec. 23, 2020 (JP) 2020-214066

(51) Int. Cl. H01L 23/053; H01L 23/10; H01L 23/31; G01L 19/14; G01L 9/00

(52) U.S. Cl. CPC H01L 23/053; H01L 23/10; H01L 23/3157; G01L 19/147; G01L 9/0041

(57) ABSTRACT

A semiconductor device includes a detector assembly mounted on a base substrate and including a detector to detect pressure, a resin package on the base substrate, and a tube supported by the resin package. The resin package includes a base portion on the base substrate and in which the detector assembly is embedded, and a projecting portion including an exposed hole that exposes the detector and projects from the base portion into the tube. The tube includes a tubular body portion and a lower flange portion supported by the base portion. The lower flange portion is inside an outer edge portion of the base portion in plan view. An outer side surface of the projecting portion is bonded to an inner circumferential surface of the tube.

### CROSS REFERENCE TO RELATED APPLICATIONS

This application claims the benefit of priority to Japanese Patent Application No. 2020-214066 filed on Dec. 23, 2020 and is a Continuation Application of PCT Application No. PCT/JP2021/035901 filed on Sep. 29, 2021. The entire contents of each application are hereby incorporated herein by reference.

### BACKGROUND OF THE INVENTION

### 1. Field of the Invention

The present invention relates to a semiconductor device that measures pressure and an electronic device including the semiconductor device.

### 2. Description of the Related Art

International Publication No. 2019/181410 discloses a pressure sensor that measures pressure. The pressure sensor is attached to the housing of a pressure measuring device or the like. The pressure sensor includes a substrate and a tubular cap bonded to a frame portion provided in a base material. An annular O-ring is fitted to the circumference of the cap. The gap between the housing and the pressure sensor is sealed by the O-ring with the pressure sensor attached to the housing. This prevents a liquid from infiltrating the housing from the outside of the housing through the gap.

However, in the pressure sensor disclosed in International Publication No. 2019/181410, the adhesive surface between the cap and the frame portion is small. When the adhesive surface is small, there is a concern that an adhesive may protrude from the cap when the cap is bonded to the frame portion. Accordingly, in the pressure sensor, complex machining for providing, in the adhesive surface, a recessed portion that accommodates the adhesive is performed to prevent the adhesive from protruding.

In contrast, in the semiconductor device that measures pressure disclosed in International Publication No. 2019/208127, a tube corresponding to the cap described above includes a flange portion overhanging outward, and the flange portion is bonded to a resin package. Since the flange portion overhangs outward, the adhesive surface between the flange portion and the resin package is larger than the adhesive surface of the cap of the pressure sensor disclosed in International Publication No. 2019/181410. Accordingly, in the semiconductor device disclosed in International Publication No. 2019/181410, the protrusion of the adhesive can be reduced without complex machining for the cap of the pressure sensor disclosed in International Publication No. 2019/181410 being required.

However, in the semiconductor device disclosed in International Publication No. 2019/208127, the problem described below occurs because the tube includes the flange portion. The semiconductor device is attached to the housing by inserting the O-ring fitted to the tube into the mounting hole provided in the housing. At this time, if the O-ring is caught in the bent edge portion of the cavity of the mounting hole, attachment of the semiconductor device and the O-ring to the housing may become difficult.

The edge portion of the cavity of the mounting hole can be chamfered to solve this problem. However, when the edge portion is chamfered, a gap may be formed between the O-ring and the chamfered portion of the housing when the semiconductor device to which the O-ring has been fitted is attached to the housing. In this case, there is a concern that a liquid cannot be sufficiently prevented from infiltrating the housing.

The outer diameter of the mounting hole can be increased such that the flange portion on the near side of the O-ring as well as the O-ring is also inserted into the mounting hole to solve this problem. This also enables insertion of the flange portion on the near side into the mounting hole, thus enabling insertion of the O-ring beyond the chamfered portion of the housing. Accordingly, the gap between the O-ring and the chamfered portion of the housing does not increase.

However, in the semiconductor device disclosed in International Publication No. 2019/208127, the mounting hole is circular because the O-ring is circular in plan view, while the flange portion is rectangular. That is, the diameter of the mounting hole needs to be increased such that the flange portion can be inserted into the mounting hole. In this case, in the middle portion on each side of the rectangle of the flange portion, the gap between the inner side surface of the housing that forms the mounting hole and the flange portion increases. As a result, the O-ring is not sufficiently supported in the middle portion, and accordingly, the O-ring may hang loosely. In this case, there is a concern that a liquid cannot be sufficiently prevented from infiltrating the housing.

The problem described above does not occur because the pressure sensor disclosed in International Publication No. 2019/181410 does not include the flange portion. However, complex machining to reduce or prevent protrusion of an adhesive is necessary as described above.

### SUMMARY OF THE INVENTION

Preferred embodiments of the present invention provide semiconductor devices that each do not need complex machining to reduce or prevent protrusion of an adhesive and can be attached to the housing so as to prevent a liquid from infiltrating the housing.

A semiconductor device according to a preferred embodiment of the present invention includes a base substrate, a detector assembly mounted on an upper surface of the base substrate, the detector assembly including a detector to detect pressure, a resin package on the upper surface of the base substrate, the detector assembly being embedded in the resin package, the resin package including an exposed hole that exposes the detector of the detector assembly upward, and a tube supported by the resin package, wherein the resin package includes a base portion on the upper surface of the base substrate and in which the detector assembly is embedded, and a projecting portion including the exposed hole and projecting upward into the tube from the base portion, the tube includes a cylindrical body portion and a flange portion overhanging from an outer side surface of the body portion over an entire or substantially an entire circumference of the body portion and supported by the base portion, at least a portion of the flange portion is located inside an outer edge portion of the base portion of the resin package in plan view, and an outer side surface of the projecting portion is bonded to an inner circumferential surface of the tube.

The semiconductor devices according to preferred embodiments of the present invention each do not need complex machining to reduce or prevent protrusion of an adhesive and can be attached to the housing so as to prevent a liquid from infiltrating the housing.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view of a semiconductor device according to a first preferred embodiment of the present invention.

FIG. 2 is a sectional view taken along line A-A in FIG. 1.

FIG. 3 is a sectional view taken along line A-A in FIG. 1 when the semiconductor device in FIG. 1 has been attached to the electronic device.

FIG. 4 is a sectional view taken along line B-B in FIG. 1 when the semiconductor device in FIG. 1 has been attached to the electronic device.

FIG. 5 is a perspective view of a semiconductor device according to a second preferred embodiment of the present invention.

FIG. 6 is a sectional view taken along line C-C in FIG. 5 when a semiconductor device in FIG. 5 has been attached to the electronic device.

FIG. 7 is a perspective view of a semiconductor device according to a third preferred embodiment of the present invention.

FIG. 8 is a sectional view taken along line D-D in FIG. 7 when a semiconductor device in FIG. 7 has been attached to the electronic device.

### DETAILED DESCRIPTION OF THE PREFERRED EMBODIMENTS

A semiconductor device according to a preferred embodiment of the present invention includes a base substrate, a detector assembly mounted on an upper surface of the base substrate, the detector assembly including a detector to detect pressure, a resin package provided on the upper surface of the base substrate, the detector assembly being embedded in the resin package, the resin package including an exposed hole that exposes the detector of the detector assembly upward, and a tube supported by the resin package, wherein the resin package includes a base portion that is provided on the upper surface of the base substrate and in which the detector assembly is embedded, and a projecting portion that includes the exposed hole and projects upward into the tube from the base portion, the tube includes a tubular body portion and a flange portion that overhangs from an outer side surface of the body portion and is supported by the base portion, at least a portion of the flange portion is located inside an outer edge portion of the base portion of the resin package in plan view, and an outer side surface of the projecting portion is bonded to an inner circumferential surface of the tube.

In this structure, at least a portion of the flange portion is located inside the outer edge portion of the base portion in plan view. Accordingly, when the semiconductor device in which the O-ring fitted to the body portion of the tube is disposed in the recessed portion of the housing of the electronic device, if the flange portion is also disposed in the recessed portion, the diameter of the recessed portion can be reduced by the length of the at least a portion of the flange portion located inside the outer edge portion of the base portion. This can reduce the gap between the flange portion and the inner side surface of the housing that defines the recessed portion.

In this structure, the outer side surface of the projecting portion is bonded to the inner circumferential surface of the tube. Even if an adhesive between the outer side surface of the projecting portion and the inner circumferential surface of the tube protrudes, the adhesive having protruded is located in the tube. Accordingly, the adhesive having protruded does not prevent the semiconductor device from being attached to the housing.

In addition, since the flange portion of the tube and the base portion of the resin package need not necessarily be bonded to each other, the contact area between the flange portion and the base portion need not be increased. In addition, complex machining to provide, in the flange portion, a recessed portion that accommodates the adhesive need not be performed.

The base portion of the resin package may be polygonal or substantially polygonal in plan view, and the flange portion of the tube may be circular or substantially circular in plan view. In this structure, the flange portion is circular or substantially circular in plan view as the O-ring to be fitted to the body portion of the tube. Accordingly, the gap between the flange portion and the inner side surface of the housing that defines the recessed portion can be reduced, and variations in the gap can be reduced or prevented.

The base portion of the resin package may include a first base portion provided on the upper surface of the base substrate and a second base portion that projects upward from the first base portion, is located inside the outer edge portion of the first base portion in plan view, and supports the flange portion of the tube.

In this structure, the second base portion is located inside the outer edge portion of the first base portion in plan view. Accordingly, when the semiconductor device in which the O-ring fitted to the body portion of the tube is disposed in the recessed portion of the housing of the electronic device, if the second base portion as well as the tube is disposed in the recessed portion, the diameter of the recessed portion can be reduced by the length of a second base portion located inside the outer edge portion of the first base portion. This can reduce the gap between the flange portion and the inner side surface of the housing that defines the recessed portion. In addition, the O-ring fitted to the body portion of the tube can be further inserted into the recessed portion by inserting the second base portion into the recessed portion.

The first base portion of the resin package may be polygonal or substantially polygonal in plan view, and the second base portion of the resin package may be circular or substantially circular in plan view. In this structure, the second base portion is circular or substantially circular in plan view as the O-ring to be fitted to the body portion of the tube. Accordingly, the gap between the second base portion and the inner side surface of the housing that defines the recessed portion can be reduced, and variations in the gap can be reduced or prevented.

The resin package may be located inside the outer edge portion of the base substrate in plan view. In this structure, the resin package is located inside the outer edge portion of the base substrate in plan view. Accordingly, when the semiconductor device in which the O-ring fitted to the body portion of the tube is disposed in the recessed portion of the housing of the electronic device, if the entire or substantially the entire resin package is disposed in the recessed portion, the diameter of the recessed portion can be reduced by the length of a resin package located inside the outer edge portion of the base substrate. This can reduce the gap between the flange portion and the inner side surface of the housing that defines the recessed portion. In addition, the O-ring fitted to the body portion of the tube can be further inserted into the recessed portion by inserting the entire or substantially the entire resin package into the recessed portion.

The base substrate may be polygonal or substantially polygonal in plan view, and the resin package may be circular or substantially circular in plan view. In this structure, the resin package is circular or substantially circular in plan view as the O-ring to be fitted to the tube. Accordingly, the gap between the resin package and the inner side surface of the housing that defines the recessed portion can be reduced, and variations in the gap can be reduced or prevented.

The body portion of the tube may be cylindrical or elliptic-cylindrical. In this structure, a gap is less likely to be provided between the O-ring and the body portion with the O-ring fitted to the body portion. As a result, a liquid is less likely to circulate through a portion between the O-ring and the body portion.

The flange portion of the tube may overhang from the outer side surface of the body portion over the entire or substantially the entire circumference of the body portion. In this structure, the flange portion can stably support the O-ring with the O-ring fitted to the body portion.

The projecting portion of the resin package may project above the flange portion of the tube. In this structure, the semiconductor device can be configured such that the projecting portion faces the O-ring across the body portion of the tube with the O-ring fitted to the body portion of the tube. As a result, since the projecting portion can receive the deformation of the body portion of the tube due to a force applied to the body portion of the tube from the O-ring, the deformation can be reduced or prevented.

The tube may be made of a metal. Since the tube is made of a metal in this structure, the dimensional accuracy of the tube can be improved.

The tube may be made of a resin. Since the tube is made of a resin in this structure, the bonding strength to bond the tube to the resin package, which is also made of a resin, can be increased.

A semiconductor device according to a preferred embodiment of the present invention may include a circuit element that is mounted on the upper surface of the base substrate and electrically connected to the detector assembly.

An electronic device according to a preferred embodiment of the present invention includes the semiconductor device, an O-ring surrounding the tube in plan view and having an inner circumferential portion in contact with the outer side surface of the body portion of the tube, and a housing to which the semiconductor device is attached.

The housing may include a recessed portion that is recessed from an inner surface of the housing toward an outer surface of the housing and in which at least the tube and the O-ring of the semiconductor device are disposed and a cavity through which the recessed portion is open to an outside of the housing and that exposes the detector of the detector assembly to the outside of the housing through the tube disposed in the recessed portion, and an inner side surface of the housing may include, in an end portion close to the inner surface of the housing, a tapered surface having an inner diameter that decreases toward the outer surface of the housing from an inner surface of the housing, the inner side surface forming the recessed portion.

In this structure, when the semiconductor device in which the O-ring fitted to the body portion of the tube is inserted into the recessed portion of the housing of the electronic device, the tapered surface makes contact with the O-ring, and accordingly, the O-ring can be smoothly guided into the recessed portion.

### First Preferred Embodiment

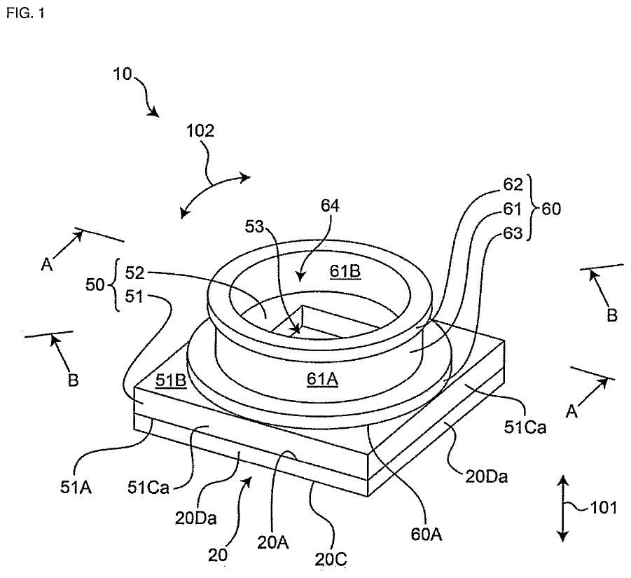

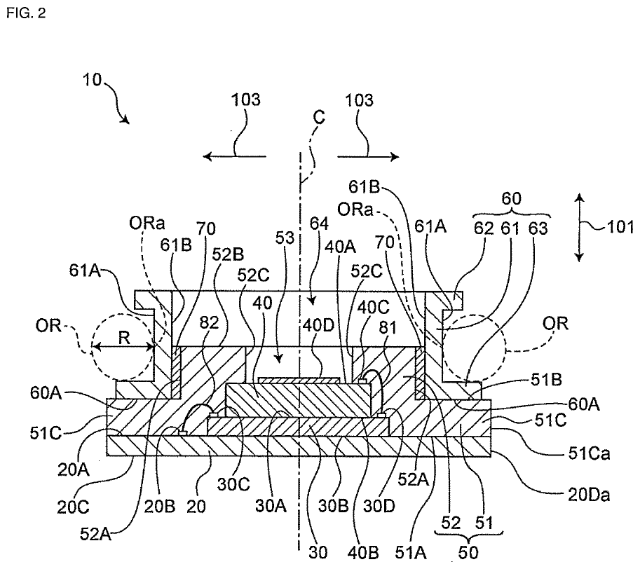

FIG. 1 is a perspective view of a semiconductor device according to a first preferred embodiment of the present invention. FIG. 2 is a sectional view taken along line A-A in FIG. 1. A height direction 101, a circumferential direction 102, and a radial direction 103 illustrated in these figures and the figures described later are intended to facilitate understanding of the present invention and do not restrict the present invention. In the height direction 101, the down side is in the direction of the base substrate 20 and the up side is in the direction of the tube 60. The circumferential direction 102 is the direction along the circumference of the tube 60, which is cylindrical. The radial direction 103 is the direction extending radially from an axial line C (see FIG. 2) of the tube 60.

The semiconductor device 10 is, for example, a pressure sensor that detects pressure. As illustrated in FIG. 1 and FIG. 2, the semiconductor device 10 includes a base substrate 20, a circuit element 30 mounted on the base substrate 20, a detector assembly 40 mounted on the base substrate 20, a resin package 50, and a tube 60.

In the first preferred embodiment, the base substrate 20 is a rigid substrate, such as for example, a glass epoxy substrate or a ceramic substrate, but the base substrate 20 is not limited to these examples. For example, the base substrate 20 may be a leadframe.

In the first preferred embodiment, the base substrate 20 is a rectangular or substantially rectangular parallelepiped that is thin in the height direction 101. That is, in the first preferred embodiment, the base substrate 20 has a quadrilateral shape in plan view. The shape of the base substrate 20 is not limited to a rectangular or substantially rectangular parallelepiped (quadrilateral in plan view). For example, the shape of the base substrate 20 may be a polygon other than a quadrilateral in plan view.

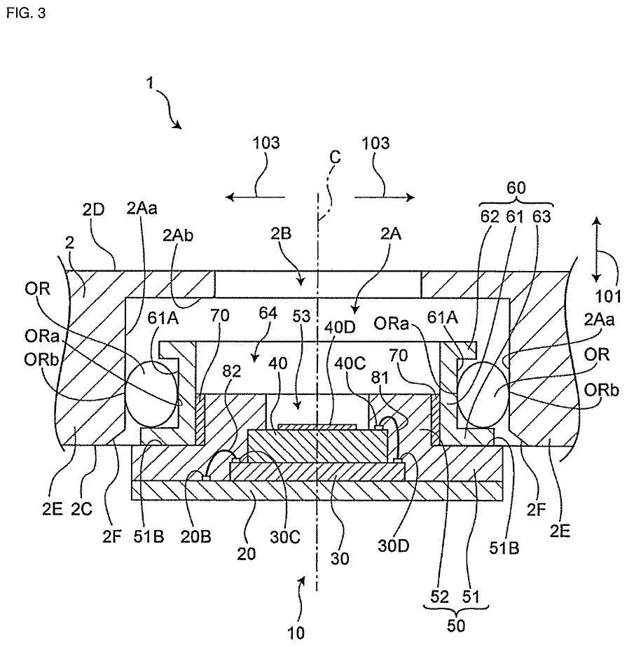

As illustrated in FIG. 2, a circuit element 30 is mounted on an upper surface 20A of the base substrate 20. The base substrate 20 includes a pad 20B on the upper surface 20A. FIG. 2 illustrates one pad 20B, but the number of pads 20B is not limited to one. The pad 20B is electrically connected to the circuit element 30 via a bonding wire 82. The base substrate 20 includes an external connection terminal, which is not illustrated, on a lower surface 20C, which is the back surface of the upper surface 20A. The semiconductor device 10 is electrically connected to another external device, such as a printed circuit board installed in the electronic device 1 (see FIG. 3), which will be described later, via an external connection terminal.

The circuit element 30 includes an upper surface 30A and a lower surface 30B, which is the back surface of the upper surface 30A. In the first preferred embodiment, the circuit element 30 includes an ASIC (application specific integrated circuit). In the first preferred embodiment, the lower surface 30B of the circuit element 30 is bonded to the upper surface 20A of the base substrate 20 with a die attach film, a die attach material, or the like.

The circuit element 30 includes a first pad 30C on the upper surface 30A. FIG. 2 illustrates only one first pad 30C, but the number of first pads 30C is not limited to one. The first pad 30C is electrically connected to the pad 20B of the base substrate 20 via the bonding wire 82.

The circuit element 30 includes a second pad 30D on the upper surface 30A separately from the first pad 30C. FIG. 2 illustrates one second pad 30D, but the number of second pads 30D is not limited to one. The second pad 30D is electrically connected to the detector assembly 40 via a bonding wire 81.

The circuit element 30 includes a signal processing circuit that processes a signal output from the detector assembly 40 and outputs the processed signal to the base substrate 20. For example, in the first preferred embodiment, the circuit element 30 includes a converter, a filter, a temperature sensor, a processor, a memory, and the like. The converter converts a voltage signal output from the detector assembly 40 into a digital signal. The filter filters the digital signal from the converter. The temperature sensor detects temperature. The processor corrects the filtered digital signal in accordance with the temperature detected by the temperature sensor. The memory stores a correction coefficient used to correct the digital signal in accordance with the detected temperature, and the like.

In the first preferred embodiment, the detector assembly 40 is a pressure sensor to measure pressure. The detector assembly 40 includes an upper surface 40A and a lower surface 40B, which is the back surface of the upper surface 40A. The detector assembly 40 is, for example, a MEMS (micro electro mechanical systems) element, such as a piezoresistive pressure sensor element or an electrostatic pressure sensor element. In the first preferred embodiment, the lower surface 40B of the detector assembly 40 is bonded to the upper surface 30A of the circuit element 30 with a die attach film, a die attach material, or the like. As a result, the detector assembly 40 is mounted on the upper surface 30A of the circuit element 30.

The detector assembly 40 includes a pad 40C on the upper surface 40A. FIG. 2 illustrates one pad 40C, but the number of pads 40C is not limited to one. The pad 40C is electrically connected to a second pad 30D of the circuit element 30 via the bonding wire 81. That is, the detector assembly 40 is electrically connected to the base substrate 20 via the circuit element 30.

The detector assembly 40 includes, on the upper surface 40A, a detector 40D to which pressure is applied. That is, the detector 40D detects pressure. In the first preferred embodiment, the detector 40D of the detector assembly 40, which is a pressure sensor element, is a membrane or a diaphragm that receives pressure. The detector 40D includes, for example, a passivation film and is waterproof.

The resin package 50 is manufactured by mold-forming a hard resin, such as a thermoset resin, for example, an epoxy molding resin, onto the upper surface 20A of the base substrate 20. That is, as illustrated in FIG. 2, the resin package 50 is provided on the upper surface 20A of the base substrate 20. An upper surface 20A portion (particularly, the pad 20B) of the base substrate 20 is protected and waterproofed by being covered with the resin package 50.

As illustrated in FIG. 2, the circuit element 30, the detector assembly 40, and the bonding wires 81 and 82 are embedded in the resin package 50. The circuit elements 30 (particularly the first pad 30C and the second pad 30D), the detector assembly 40 (particularly the pad 40C), and the bonding wires 81, 82 are protected and waterproofed by being embedded in the resin package 50.

Accordingly, the electrical connection between the base substrate 20 and the circuit element 30 and the electrical connection between the circuit element 30 and the detector assembly 40 are waterproofed by the resin package 50.

As illustrated in FIG. 1 and FIG. 2, the resin package 50 includes a base portion 51 and a projecting portion 52.

The base portion 51 defines a resin package 50 portion close to the base substrate 20. That is, the base portion 51 defines the lower portion of the resin package 50. As illustrated in FIG. 2, a lower surface 51A of the base portion 51 is in contact with the upper surface 20A of the base substrate 20. That is, the base portion 51 is provided on the upper surface 20A of the base substrate 20.

In the first preferred embodiment, the base portion 51 is a rectangular or substantially rectangular parallelepiped that is thin in the height direction 101. That is, the base portion 51 is a quadrilateral in plan view in the first preferred embodiment. In plan view, the base portion 51 and the base substrate 20 have the same or substantially the same shape and the same or substantially the same size. Accordingly, an outer side surface 51Ca of the base portion 51 and an outer side surface 20 Da of the base substrate 20 are flush with each other.

The shape of the base portion 51 is not limited to a rectangular or substantially rectangular parallelepiped (quadrilateral in plan view). For example, the shape of the base portion 51 may be a polygon other than a quadrilateral in plan view. In addition, the shape of the base portion 51 may be a non-polygon, such as a circle in plan view. In addition, in plan view, the base portion 51 and the base substrate 20 may have different shapes and/or different sizes.

The projecting portion 52 defines a resin package 50 portion on the opposite side of the base substrate 20 across the base portion 51. That is, the projecting portion 52 defines an upper portion of the resin package 50. The projecting portion 52 projects from the base portion 51 away from the base substrate 20. In other words, the projecting portion 52 projects upward from the base portion 51.

The projecting portion 52 enters the tube 60, which will be described later.

In the first preferred embodiment, the projecting portion 52 is provided in a central portion of the base portion 51 in plan view. In other words, in plan view, the base portion 51 extends to the outside of an outer side surface 52A of the projecting portion 52.

In the first preferred embodiment, the circuit element 30, a lower portion of the detector assembly 40, a lower portion of the bonding wire 81, and the bonding wire 82 are embedded in the base portion 51. In the first preferred embodiment, an upper portion of the detector assembly 40 and an upper portion of the bonding wire 81 are buried in the projecting portion 52.

A lower portion of the circuit element 30 may be embedded in the base portion 51, and an upper portion of the circuit element 30 may be embedded in the projecting portion 52. Alternatively, a lower portion of the bonding wire 82 may be embedded in the base portion 51, and an upper portion of the bonding wire 82 may be embedded in the projecting portion 52. Alternatively, the entire or substantially the entire detector assembly 40 may be embedded in the base portion 51. Alternatively, the entire or substantially the entire the bonding wire 81 may be embedded in the base portion 51.

The projecting portion 52 includes an exposed hole 53. The exposed hole 53 passes through the projecting portion 52 vertically. That is, the projecting portion 52 is tubular.

The outer shape of the projecting portion 52 matches the shape of an inner circumferential surface 61B of the body portion 61 of the tube 60, which will be described later. As described later, in the first preferred embodiment, the shape of the inner circumferential surface 61B of the body portion 61 of the tube 60 is circular or substantially circular in plan view. Accordingly, the outer shape of the projecting portion 52 is also circular or substantially circular in plan view. That is, the projecting portion 52 is cylindrical in the first preferred embodiment. When the shape of the inner circumferential surface 61B of the tube 60 is non-circular in plan view, the outer shape of the projecting portion 52 is also a shape other than circular or substantially circular. For example, when the shape of the inner circumferential surface 61B of the tube 60 is a quadrilateral in plan view, the outer shape of the projecting portion 52 is a quadrilateral tube.

A portion of the upper surface 40A of the detector assembly 40 and the detector 40D face the lower end portion of the exposed hole 53. That is, a portion of the upper surface 40A of the detector assembly 40 and the detector 40D are exposed to the outside of the resin package 50 through the exposed hole 53. That is, the exposed hole 53 exposes the detector 40D of the detector assembly 40 to the outside of the resin package 50.

The cavity of the exposed hole 53 is provided in an upper surface 52B of the projecting portion 52. That is, the resin package 50 exposes the detector 40D of the detector assembly 40 upward. A pressure acts on the detector 40D of the detector assembly 40 from the outside of the semiconductor device 10 through the tube 60 and the exposed hole 53, which will be described later, and accordingly, the detector assembly 40 can measure the pressure.

The projecting portion 52 is located around the detector 40D of the detector assembly 40 in plan view. That is, the projecting portion 52 is located outside the detector 40D in plan view.

The detector 40D, which is a detector assembly 40 portion exposed to the outside through the exposed hole 53, is waterproofed by, for example, a passivation film. In addition, in the first preferred embodiment, the exposed hole 53 has a quadrilateral shape in plan view but may have another shape (for example, a circular or substantially circular in plan view). The exposed hole 53 need only define and function as a pressure introduction hole through which pressure is introduced into the detector 40D.

In the first preferred embodiment, the tube 60 is made of a metal, such as stainless steel, for example. The tube may be made of a material other than a metal. For example, the tube may be made of a resin. The resin described above is, for example, a hard resin that makes up the resin package 50.

As illustrated in FIG. 1 and FIG. 2, the tube 60 includes the body portion 61, an upper flange portion 62, and a lower flange portion 63. The lower flange portion 63 is an example of the flange portion. The body portion 61, the upper flange portion 62, and the lower flange portion 63 may be integrally molded or may be separate members and then combined together by fitting or the like.

The body portion 61 is cylindrical in the first preferred embodiment. The projecting portion 52 of the resin package 50 enters an interior space 64 of the body portion 61 from below. As described above, the outer shape of the projecting portion 52 matches the shape of the inner circumferential surface 61B of the body portion 61 of the tube 60. Accordingly, the outer side surface 52A of the projecting portion 52 faces the inner circumferential surface 61B of the body portion 61. In the first preferred embodiment, a slight gap is provided between the outer side surface 52A of the projecting portion 52 and the inner circumferential surface 61B of the body portion 61. An adhesive 70 is present in this gap. That is, the outer side surface 52A of the projecting portion 52 is bonded to the inner circumferential surface 61B of the body portion 61. It should be noted that the outer side surface 52A of the projecting portion 52 may be in contact with the inner circumferential surface 61B of the body portion 61.

The upper flange portion 62 overhangs in the radial direction 103 from an outer side surface 61A of the body portion 61. The upper flange portion 62 is located in the upper end portion of the body portion 61. The upper flange portion 62 overhangs over the entire or substantially the entire circumference of the outer side surface 61A in the circumferential direction 102. The upper flange portion 62 is circular or substantially circular in plan view.

The upper flange portion 62 may be located at a position other than the upper end portion of the body portion 61. In addition, the upper flange portion 62 may overhang from a portion of the outer side surface 61A in the circumferential direction 102. For example, the tube 60 may include a plurality of upper flange portions 62 disposed at intervals in the circumferential direction 102. In addition, the upper flange portion 62 may be non-circular in plan view, for example, quadrilateral in plan view.

The lower flange portion 63 overhangs in the radial direction 103 from the outer side surface 61A of the body portion 61. The lower flange portion 63 is spaced apart in the height direction 4 below the upper flange portion 62. The lower flange portion 63 is disposed in the lower end portion of the body portion 61. The lower flange portion 63 overhangs over the entire or substantially the entire circumference of the outer side surface 61A in the circumferential direction 102. The lower flange portion 63 is circular or substantially circular in plan view.

As illustrated in FIG. 2, a lower surface 60A of the lower flange portion 63 is in contact with an upper surface 51B of the base portion 51 of the resin package 50 from above. That is, the lower flange portion 63 is supported by the base portion 51 of the resin package 50.

The lower flange portion 63 is located inside an outer edge portion 51C of the base portion 51 of the resin package 50 in plan view. The outer edge portion 51C of the base portion 51 is defined by the outer side surface 51Ca of the base portion 51 and a base portion 51 portion in the vicinity of the outer side surface 51Ca.

The lower flange portion 63 may be located at a position other than the lower end portion of the body portion 61. In this case, for example, the lower end portion of the body portion 61 is located below the lower flange portion 63, and the lower end portion of the body portion 61 is supported by the base portion 51 of the resin package 50. In addition, the lower flange portion 63 may overhang from a portion of the outer side surface 61A in the circumferential direction 102. For example, the tube 60 may include a plurality of lower flange portions 63 disposed at intervals in the circumferential direction 102. In addition, the lower flange portion 63 may be non-circular in plan view, for example, quadrilateral in plan view.

The upper surface 52B of the projecting portion 52 is located above the lower flange portion 63 with the projecting portion 52 of the resin package 50 entering the body portion 61 from below. That is, the projecting portion 52 projects above the lower flange portion 63. The position of the upper surface 52B of the projecting portion 52 is not limited to the position illustrated in FIG. 2. For example, the upper surface 52B of the projecting portion 52 may be located below the upper end of the lower flange portion 63. In addition, for example, the upper surface 52B of the projecting portion 52 may be flush with the upper end portion of the tube 60.

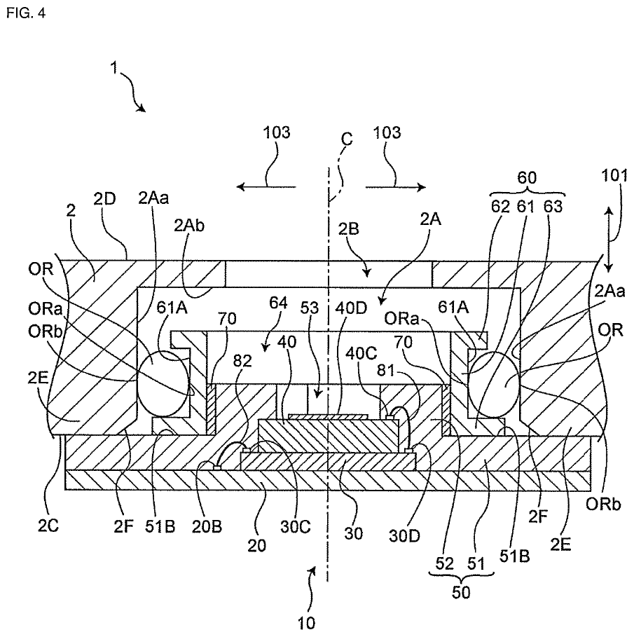

FIG. 3 is a sectional view taken along line A-A in FIG. 1 when the semiconductor device in FIG. 1 has been attached to the electronic device. FIG. 4 is a sectional view taken along line B-B in FIG. 1 when the semiconductor device in FIG. 1 has been attached to the electronic device.

As illustrated in FIG. 3 and FIG. 4, the semiconductor device 10 is used with the semiconductor device 10 attached to the housing 2 of the electronic device 1. The electronic device 1 is, for example, a pressure measuring device and includes the semiconductor device 10, the O-ring OR, and the housing 2.

The O-ring OR is fitted to the tube 60 of the semiconductor device 10. The O-ring OR is annular. The inner diameter of the O-ring OR is identical or substantially identical to the outer diameter of the body portion 61 of the tube 60. The O-ring OR is made of an easily compression-deformable member such as nitrile rubber, for example.

As illustrated by the dashed line in FIG. 2, the O-ring OR is disposed to surround the body portion 61 of the tube 60 in plan view. In the first preferred embodiment, the inner diameter of the O-ring OR is greater than the outer diameter of the body portion 61.

As illustrated in FIG. 2, the upper flange portion 62 of the tube 60 prevents the O-ring OR attached to the body portion 61 of the tube 60 from being removed from the upper end portion of the body portion 61. The lower flange portion 63 of the tube 60 prevents the O-ring OR attached to the body portion 61 from being removed from the lower end portion of the body portion 61. The tube 60 need not include the upper flange portion 62. In this case, the O-ring OR has an inner diameter smaller than the outer diameter of the body portion 61 to prevent the O-ring OR from loosely fitting.

As illustrated in FIG. 3 and FIG. 4, the housing 2 includes a recessed portion 2A and a cavity 2B.

The recessed portion 2A is recessed from an inner surface 2C of the housing 2 to an outer surface 2D of the housing 2. The inner surface 2C of the housing 2 faces the interior space of the housing 2. The outer surface 2D of the housing 2 is the back surface of the inner surface 2C and faces the outside of the housing 2. The semiconductor device 10 to which the O-ring OR has been attached is disposed in the recessed portion 2A. In the first preferred embodiment, the O-ring OR, the tube 60, the projecting portion 52 of the resin package 50, and the upper portion of the detector assembly 40 are disposed in the recessed portion 2A.

The semiconductor device 10 disposed in the recessed portion 2A is attached to the housing 2 by known methods, which is not illustrated, such as fitting. In addition, semiconductor device 10 portions disposed in the recessed portion 2A are not limited to the portions described above. At least the O-ring OR and the tube 60 of the semiconductor device 10 need only be disposed in the recessed portion 2A.

The cavity 2B passes through the housing 2. The outside of the housing 2 communicates with the recessed portion 2A through the cavity 2B. That is, the recessed portion 2A is open to the outside of the housing 2 through the cavity 2B. The detector 40D of the detector assembly 40 of the semiconductor device 10 communicates with the outside of the electronic device 1 through the exposed hole 53 of the resin package 50, the interior space 64 of the body portion 61 of the tube 60, the recessed portion 2A of the housing 2, and the cavity 2B of the housing 2. That is, the cavity 2B exposes the detector 40D to the outside of the housing 2 through the tube 60. This enables the semiconductor device 10 to measure the pressure outside the electronic device 1.

The O-ring OR is disposed in the gap between the semiconductor device 10 disposed as described above and an inner side surface 2Aa that defines the recessed portion 2A of the housing 2.

When the semiconductor device 10 is disposed in the recessed portion 2A of the housing 2, the length in the radial direction 103 between the outer side surface 61A of the body portion 61 of the tube 60 and the inner side surface 2Aa that defines the recessed portion 2A is shorter than a diameter R (see FIG. 2) of the O-ring OR. Accordingly, when the semiconductor device 10 is disposed in the recessed portion 2A, the O-ring OR undergoes compression deformation (see FIG. 3 and FIG. 4). This causes an inner circumferential portion ORa of the O-ring OR to make contact with the outer side surface 61A of the body portion 61 of the tube 60, and an outer circumferential portion ORb of the O-ring OR to make contact with the inner side surface 2Aa that defines the recessed portion 2A. As a result, the gap between the semiconductor device 10 and the housing 2 is sealed, and a liquid is prevented, by the O-ring OR, from infiltrating the electronic device 1 from the outside of the electronic device 1 through the gap.

The inner side surface 2Aa, which defines the recessed portion 2A of the housing 2, includes a tapered surface 2F in an end portion 2E of the housing 2 close to the inner surface 2C. The end portion 2E of the housing 2 close to the inner surface 2C includes the inner surface 2C of the housing 2 and a housing 2 portion in the vicinity of the inner surface 2C. The tapered surface 2F is inclined with respect to the height direction 4. The tapered surface 2F approaches the axial line C of the tube 60 toward the outer surface 2D from the inner surface 2C. In other words, the tapered surface 2F is inclined with respect to the height direction 4 toward the outer surface 2D from the inner surface 2C such that the inner diameter of the recessed portion 2A is smaller. The tapered surface 2F may be present or absent.

The semiconductor device 10 is inserted into the recessed portion 2A from the interior space side of the housing 2, starting with the upper flange portion 62 of the tube 60. In the process of inserting the semiconductor device 10 into the recessed portion 2A, the O-ring OR makes contact with the tapered surface 2F from the interior space side of the housing 2.

When the semiconductor device 10 is further inserted into the recessed portion 2A, the O-ring OR is guided along the tapered surface 2F. At this time, a reaction force from the tapered surface 2F acts on the O-ring OR. This reaction force includes a component in the direction of the axial line C. This component compresses the O-ring OR. The compressed O-ring OR passes through the tapered surface 2F. Accordingly, as described above, the inner circumferential portion ORa of the O-ring OR makes contact with the outer side surface 61A of the body portion 61 of the tube 60, and the outer circumferential portion ORb of the O-ring OR makes contact with the inner side surface 2Aa, which forms the recessed portion 2A. As a result, the gap between the semiconductor device 10 and the housing 2 is sealed.

When the semiconductor device 10 is further inserted into the recessed portion 2A, the upper surface 51B of the base portion 51 of the resin package 50 makes contact with the inner surface 2C of the housing 2, as illustrated in FIG. 4.

Specifically, of the quadrilateral upper surface 51B of the base portion 51, the peripheral portions of the vertexes of the quadrilateral make contact with the inner surface 2C of the housing 2. This positions the semiconductor device 10 with respect to the housing 2. That is, the semiconductor device 10 is prevented from being inserted into the recessed portion 2A more than necessary.

With the peripheral portions described above in contact with the inner surface 2C of the housing 2, as illustrated in FIG. 3, the middle portion (in other words, the middle portion of two adjacent vertexes) of each side of the quadrilateral of the quadrilateral upper surface 51B of the base portion 51 is not contact with the inner surface 2C of the housing 2.

In the first preferred embodiment, the lower flange portion 63 is located inside the outer edge portion 51C of the base portion 51 in plan view. Accordingly, when the semiconductor device 10 in which the O-ring OR fitted to the body portion 61 of the tube 60 is disposed in the recessed portion 2A of the housing 2 of the electronic device 1, if the lower flange portion 63 is also disposed in the recessed portion 2A, the diameter of the recessed portion 2A can be reduced by the length of a lower flange portion 63 part located inside the outer edge portion 51C of the base portion 51. This can reduce the gap between the lower flange portion 63 and the inner side surface 2Aa of the housing 2 that defines the recessed portion 2A. The lower flange portion 63 is located inside the outer edge portion 51C of the base portion 51 in plan view in the first preferred embodiment, but a portion of the lower flange portion 63 may be disposed outside the outer edge portion 51C of the base portion 51. For example, a portion of the lower flange portion 63 may be located outside the middle portions of the four sides of the upper surface 51B of the base portion 51. That is, when the peripheral portions of the vertexes of the upper surface 51B of the base portion 51 are located outside the lower flange portion 63, the peripheral portions make contact with the inner surface 2C of the housing 2 and position the semiconductor device 10 with respect to the housing 2.

In the first preferred embodiment, the outer side surface 52A of the projecting portion 52 is bonded to the inner circumferential surface 61B of the tube 60. Even if the adhesive 70 between the outer side surface 52A of the projecting portion 52 and the inner circumferential surface 61B of the tube 60 protrudes, the adhesive 70 having protruded is located in the interior space 64 of the tube 60 or located below the lower flange portion 63 of the tube 60. Accordingly, the adhesive 70 having protruded does not prevent the semiconductor device 10 from being attached to the housing 2.

In addition, since the lower flange portion 63 of the tube 60 need not necessarily be bonded to the base portion 51 of the resin package 50, the contact area between the lower flange portion 63 and the base portion 51 need not be increased. In addition, complex processing for providing, in the lower flange portion 63, a recessed portion to accommodate the adhesive is not necessary.

In the first preferred embodiment, the lower flange portion 63 is circular or substantially circular in plan view as the O-ring OR to be fitted to the body portion 61 of the tube 60. Accordingly, the gap between the lower flange portion 63 and the inner side surface 2Aa of the housing 2 that defines the recessed portion 2A can be reduced, and variations in the gap can be reduced or prevented.

In the first preferred embodiment, the body portion 61 is cylindrical. This makes a gap less likely to be provided between the O-ring OR and the body portion 61 with the O-ring OR fitted to the body portion 61. As a result, a liquid is less likely to circulate through a portion between the O-ring OR and the body portion 61.

In the first preferred embodiment, the lower flange portion 63 overhangs from the outer side surface 61A of the body portion 61 over the entire or substantially the entire circumference of the body portion 61. Accordingly, the lower flange portion 63 can stably support the O-ring OR with the O-ring OR fitted to the body portion 61.

In the first preferred embodiment, the projecting portion 52 projects above the lower flange portion 63 of the tube 60. Accordingly, the semiconductor device 10 can be configured such that the projecting portion 52 faces the O-ring OR in the radial direction 103 across the body portion 61 of the tube 60 with the O-ring OR fitted to the body portion 61 of the tube 60. As a result, since the deformation of the body portion 61 of the tube 60 due to the force applied by the O-ring OR to the body portion 61 of the tube 60 can be received by the projecting portion 52, the deformation can be reduced or prevented.

Since the tube 60 is made of a metal in the first preferred embodiment, the dimensional accuracy of the tube 60 can be improved.

When the tube 60 is made of a resin, the bonding strength for bonding the tube 60 to the resin package 50, which is also made of a resin, can be increased.

In the first preferred embodiment, when the semiconductor device 10 in which the O-ring OR fitted to the body portion 61 of the tube 60 is inserted into the recessed portion 2A of the housing 2 of the electronic device 1, the tapered surface 2F is in contact with the O-ring OR, and accordingly, the O-ring OR can be smoothly guided into the recessed portion 2A.

In the first preferred embodiment, the body portion 61 of the tube 60 is not limited to cylindrical as long as it is tubular. For example, the body portion 61 may be elliptic-cylindrical or a polygonal-tubular. When the body portion 61 is polygonal-tubular, the body portion 61 preferably has a greater number of angles because the gap between the body portion 61 and the O-ring OR is less likely to be formed.

The detector assembly 40 is mounted on the upper surface 30A of the circuit element 30 in the first preferred embodiment, but the detector assembly 40 may be mounted on the upper surface 20A of the base substrate 20 via bonding or the like.

In the first preferred embodiment, the circuit element 30 is electrically connected to the base substrate 20 via the bonding wire 82, and the detector assembly 40 is electrically connected to the circuit element 30 via the bonding wire 81. However, the connection modes of the base substrate 20, the circuit element 30, and the detector assembly 40 are not limited to this example. For example, the detector assembly 40 may be connected to the base substrate 20 via the bonding wire as in the circuit element 30. In this case, the detector assembly 40 is electrically connected to the circuit element 30 via the base substrate 20.

In the first preferred embodiment, the base substrate 20, the circuit element 30, and the detector assembly 40 are electrically connected via the bonding wires 81 and 82. However, the base substrate 20, the circuit element 30, and the detector assembly 40 may be electrically connected by configurations other than the bonding wires 81 and 82. For example, the circuit element 30 may be mounted on the base substrate 20 by flip chip bonding. In this case, the circuit element 30 and the base substrate 20 are electrically connected to each other by soldering.

### Second Preferred Embodiment

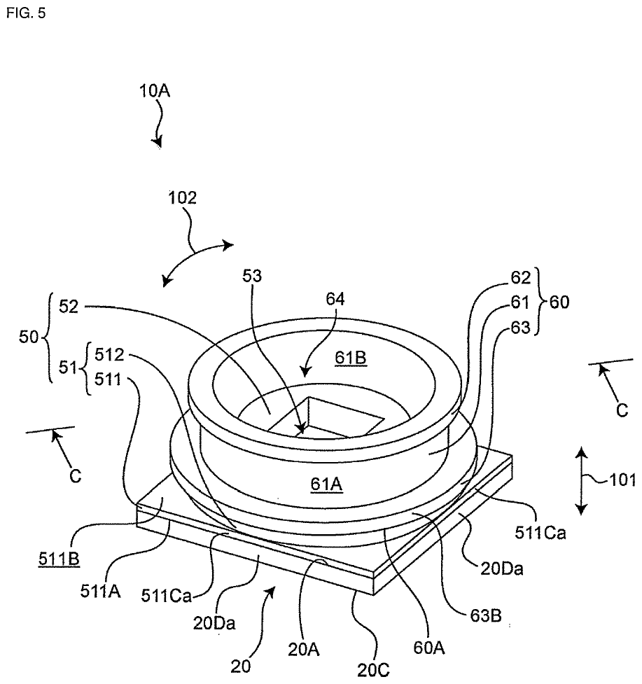

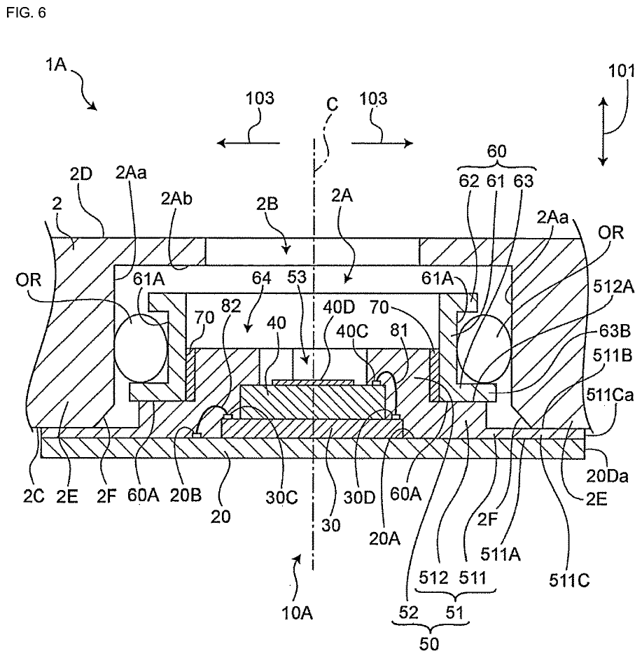

FIG. 5 is a perspective view of a semiconductor device according to a second preferred embodiment of the present invention. FIG. 6 is a sectional view taken along line C-C in FIG. 5 when a semiconductor device in FIG. 5 has been attached to the electronic device. A semiconductor device 10A according to the second preferred embodiment differs from the semiconductor device 10 according to the first preferred embodiment in that the base portion 51 of the resin package 50 includes a first base portion 511 and a second base portion 512.

As illustrated in FIG. 5 and FIG. 6, the base portion 51 of the resin package 50 includes the first base portion 511 and the second base portion 512.

The first base portion 511 defines a portion of the base portion 51 close to the base substrate 20. That is, the first base portion 511 defines a lower portion of the base portion 51. A lower surface 511A of first base portion 511 is in contact with the upper surface 20A of the base substrate 20. That is, the first base portion 511 is provided on the upper surface 20A of the base substrate 20.

In the second preferred embodiment, the first base portion 511 is a rectangular or substantially rectangular parallelepiped that is thin in the height direction 101. That is, in the second preferred embodiment, the first base portion 511 is quadrilateral in plan view. In plan view, the first base portion 511 and the base substrate 20 have the same or substantially the same shape and the same or substantially the same size. Accordingly, an outer side surface 511Ca of the first base portion 511 is flush with the outer side surface 20 Da of the base substrate 20.

The shape of the first base portion 511 is not limited to a rectangular or substantially rectangular parallelepiped (quadrilateral in plan view). For example, the shape of the first base portion 511 may be a polygon other than a quadrilateral in plan view. In addition, the first base portion 511 may be non-polygonal, for example, circular or substantially circular in plan view. In addition, in plan view, the first base portion 511 and the base substrate 20 may have different shapes or different sizes.

The second base portion 512 defines a portion of a base portion 51 on the opposite side of the base substrate 20 across the first base portion 511. That is, the second base portion 512 defines an upper portion of the base portion 51. The second base portion 512 projects from the first base portion 511 away from the base substrate 20. In other words, the second base portion 512 projects upward from the first base portion 511.

In the second preferred embodiment, the second base portion 512 is cylindrical. That is, the second base portion 512 is circular or substantially circular in plan view. The second base portion 512 may be non-cylindrical, for example, quadrangular prism-shaped. In this case, the second base portion 512 is quadrilateral in plan view.

As illustrated in FIG. 6, an upper surface 512A of second base portion 512 makes contact with the lower surface 60A of the lower flange portion 63 of the tube 60 from below. That is, the second base portion 512 supports the lower flange portion 63 of the tube 60.

As illustrated in FIG. 5 and FIG. 6, the second base portion 512 is located inside an outer edge portion 511C of the first base portion 511 in plan view. The outer edge portion 511C of the first base portion 511 is defined of the outer side surface 511Ca of the first base portion 511 and a first base portion 511 part in the vicinity of the outer side surface 511Ca.

The projecting portion 52 projects upward from second base portion 512.

As illustrated in FIG. 6, the semiconductor device 10A according to the second preferred embodiment is inserted into the recessed portion 2A of the housing 2 as the semiconductor device 10 according to the first preferred embodiment. An electronic device 1A includes the semiconductor device 10A, the O-ring OR attached to the semiconductor device 10A, and the housing 2.

An upper surface 511B of first base portion 511 is in contact with the inner surface 2C of the housing 2 with the semiconductor device 10A inserted into the recessed portion 2A of the housing 2. Specifically, of the quadrilateral upper surface 511B of the first base portion 511, the peripheral portions of the vertexes of the quadrilateral are in contact with the inner surface 2C of the housing 2. This positions the semiconductor device 10A with respect to the housing 2.

As in the first preferred embodiment, with the peripheral portions described above in contact with the inner surface 2C of the housing 2, the middle portion (in other words, the middle portion of two adjacent vertexes) of each side of the quadrilateral of the quadrilateral upper surface 511B of the first base portion 511 is not in contact with the inner surface 2C of the housing 2.

In the second preferred embodiment, the O-ring OR, the tube 60, the projecting portion 52 and the second base portion 512 of the resin package 50, the upper portion of the detector assembly 40, and the upper portion of the circuit element 30 are disposed in the recessed portion 2A.

In the second preferred embodiment, the second base portion 512 is located inside the outer edge portion 511C of the first base portion 511 in plan view. Accordingly, when the semiconductor device 10A in which the O-ring OR fitted to the body portion 61 of the tube 60 is disposed in the recessed portion 2A of the housing 2 of the electronic device 1A, if the second base portion 512 in addition to the tube 60 is also disposed in the recessed portion 2A, the diameter of the recessed portion 2A can be reduced by the length of a second base portion 512 part located inside the outer edge portion 511C of the first base portion 511. This can reduce the gap between the lower flange portion 63 and the inner side surface 2Aa of the housing 2 that forms the recessed portion 2A. In addition, the O-ring OR fitted to the body portion 61 of the tube 60 can be further inserted into the recessed portion 2A by inserting the second base portion 512 into the recessed portion 2A.

In the second preferred embodiment, the second base portion 512 is circular or substantially circular in plan view as the O-ring OR to be fitted to the body portion 61 of the tube 60. Accordingly, the gap between the second base portion 512 and the inner side surface 2Aa of the housing 2 that defines the recessed portion 2A can be reduced, and variations in the gap can be reduced or prevented.

### Third Preferred Embodiment

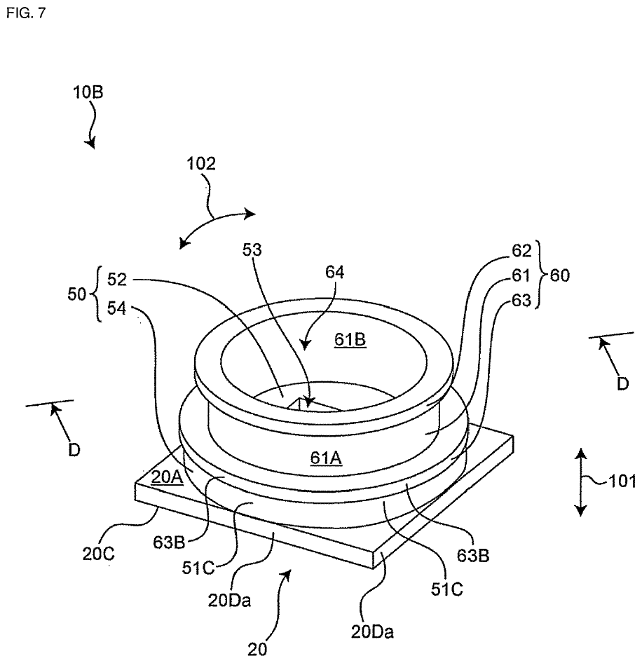

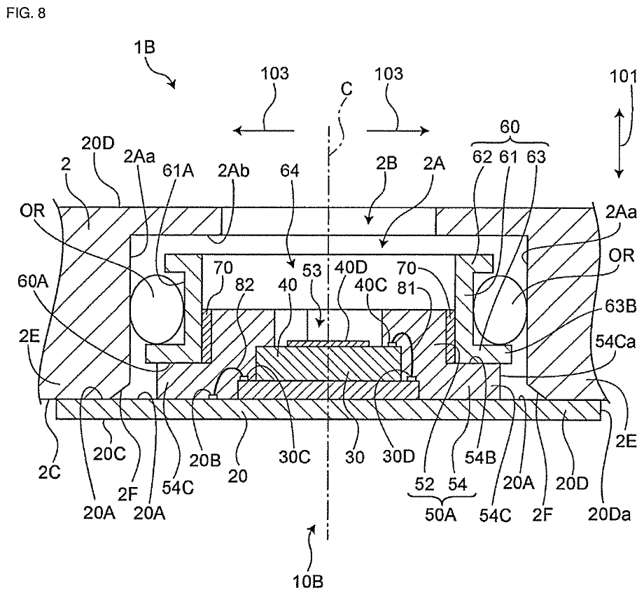

FIG. 7 is a perspective view of a semiconductor device according to a third preferred embodiment of the present invention. FIG. 8 is a sectional view taken along line D-D in FIG. 7 when a semiconductor device in FIG. 7 has been attached to the electronic device. A semiconductor device 10B according to the third preferred embodiment differs from the semiconductor device 10 according to the first preferred embodiment in that a resin package 50A is located inside the outer edge portion of the base substrate 20 in plan view.

As illustrated in FIG. 7 and FIG. 8, the semiconductor device 10B includes the resin package 50A.

The resin package 50A includes a base portion 54 that has a different structure from the base portion 51 according to the first preferred embodiment, and the projecting portion 52 that has the same or substantially the same structure as the first preferred embodiment and projects upward from the base portion 54.

The base portion 54 is located inside an outer edge portion 20D (see FIG. 8) of the base substrate 20 in plan view. The outer edge portion 20D of the base substrate 20 includes the outer side surface 20 Da of the base substrate 20 and a base substrate 20 portion in the vicinity of the outer side surface 20 Da. The base portion 54 has a structure that differs from that of the base portion 51 (see FIG. 1) that has the same or substantially the same size as the base substrate 20 in plan view.

In other words, an outer edge portion 54C of the base portion 54 is located inside the outer edge portion 20D of the base substrate 20 in plan view. The outer edge portion 54C of the base portion 54 includes an outer side surface 54Ca of the base portion 54 and a base portion 54 portion in the vicinity of the outer side surface 54Ca.

In addition, the projecting portion 52 is located inside the outer edge portion 54C of the base portion 54 in plan view.

As described above, the resin package 50A including the base portion 54 and the projecting portion 52 is located inside the outer edge portion 20D of the base substrate 20 in plan view.

In the third preferred embodiment, the base portion 54 is cylindrical. That is, the base portion 54 is circular or substantially circular in plan view. That is, the resin package 50 including the base portion 54 is circular or substantially circular in plan view. The base portion 54 may be non-cylindrical. For example, the base portion 54 may be quadrangular prism-shaped. In this case, the resin package 50 including the base portion 54 is quadrilateral in plan view.

In the third preferred embodiment, the base substrate 20 is a rectangular or substantially rectangular parallelepiped that is thin in the height direction 101 as in the first preferred embodiment. That is, the base substrate 20 is quadrilateral in plan view. The shape of the base substrate 20 is not limited to a rectangular parallelepiped (quadrilateral in plan view). For example, the shape of the base substrate 20 may be a polygon other than a quadrilateral in plan view.

As illustrated in FIG. 8, an upper surface 54B of the base portion 54 is in contact with the lower surface 60A of the lower flange portion 63 of the tube 60 from below. That is, the base portion 54 supports the lower flange portion 63 of the tube 60.

The semiconductor device 10B according to the third preferred embodiment is inserted into the recessed portion 2A of the housing 2 as the semiconductor device 10 according to the first preferred embodiment. An electronic device 1B includes the semiconductor device 10B, the O-ring OR attached to the semiconductor device 10B, and the housing 2.

The upper surface 20A of the base substrate 20 is in contact with the inner surface 2C of the housing 2 with the semiconductor device 10B inserted into the recessed portion 2A of the housing 2. Specifically, of the quadrilateral upper surface 20A of the base substrate 20, the peripheral portions of the vertexes the quadrilateral are in contact with the inner surface 2C of the housing 2. This positions the semiconductor device 10B with respect to the housing 2.

As in the first preferred embodiment, with the peripheral portions described above in contact with the inner surface 2C of the housing 2, the middle portion (in other words, the middle portion of two adjacent vertexes) of each side of the quadrilateral of the quadrilateral upper surface 20A of the base substrate 20 is not in contact with the inner surface 2C of the housing 2.

In the third preferred embodiment, all portions of the semiconductor device 10B with the exception of the base substrate 20 are disposed in the recessed portion 2A.

In the third preferred embodiment, the resin package 50A is disposed inside the outer edge portion 20D of the base substrate 20 in plan view. Accordingly, when the semiconductor device 10B in which the O-ring OR fitted to the body portion 61 of the tube 60 is disposed in the recessed portion 2A of the housing 2 of the electronic device 1B, if the entire or substantially the entire resin package 50A is disposed in the recessed portion 2A, the diameter of the recessed portion 2A can be reduced by the length of a resin package 50A portion located inside the outer edge portion 20D of the base substrate 20. This can reduce the gap between the lower flange portion 63 and the inner side surface 2Aa of the housing 2 that defines the recessed portion 2A. In addition, the O-ring OR fitted to the body portion 61 of the tube 60 can be further inserted into the recessed portion 2A by inserting the entire or substantially the entire resin package 50A into the recessed portion 2A.

In the third preferred embodiment, the resin package 50A is circular or substantially circular in plan view as the O-ring OR to be fitted to the tube 60. Accordingly, the gap between the resin package 50A and the inner side surface 2Aa of the housing 2 that defines the recessed portion 2A can be reduced, and variations in the gap can be reduced or prevented.

The advantageous effects the preferred embodiments can be obtained by combining any of the preferred embodiments described above as appropriate.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A semiconductor device comprising:
a base substrate;
a detector assembly mounted on an upper surface of the base substrate, the detector assembly including a detector to detect pressure;
a resin package on the upper surface of the base substrate, the detector assembly being embedded in the resin package, the resin package including an exposed hole exposing the detector of the detector assembly upward; and
a tube supported by the resin package; wherein
the resin package includes a base portion on the upper surface of the base substrate and in which the detector assembly is embedded, and a projecting portion including the exposed hole and projecting upward into the tube from the base portion;
the tube includes a tubular body portion and a flange portion that overhangs from an outer side surface of the body portion and is supported by the base portion;
at least a portion of the flange portion is located inside an outer edge portion of the base portion of the resin package in plan view; and
an outer side surface of the projecting portion is bonded to an inner circumferential surface of the tube.

2. The semiconductor device according to claim 1, wherein the base portion of the resin package is polygonal in plan view, and the flange portion of the tube is circular or substantially circular in plan view.

3. The semiconductor device according to claim 2, wherein the base portion of the resin package includes a first base portion on the upper surface of the base substrate and a second base portion projecting from the first base portion, is located inside an outer edge portion of the first base portion in plan view, and supports the flange portion of the tube.

4. The semiconductor device according to claim 3, wherein the first base portion of the resin package is polygonal in plan view, and the second base portion of the resin package is circular or substantially circular in plan view.

5. The semiconductor device according to claim 1, wherein the resin package is located inside an outer edge portion of the base substrate in plan view.

6. The semiconductor device according to claim 5, wherein the base substrate is polygonal in plan view, and the resin package is circular or substantially circular in plan view.

7. The semiconductor device according to claim 1, wherein the body portion of the tube is cylindrical or elliptic-cylindrical.

8. The semiconductor device according to claim 1, wherein the flange portion of the tube overhangs from the outer side surface of the body portion over an entire or substantially an entire circumference of the body portion.

9. The semiconductor device according to claim 1, wherein the projecting portion of the resin package projects above the flange portion of the tube.

10. The semiconductor device according to claim 1, wherein the tube is made of a metal.

11. The semiconductor device according to claim 1, wherein the tube is made of a resin.

12. The semiconductor device according to claim 1, further comprising a circuit element mounted on the upper surface of the base substrate and electrically connected to the detector assembly.

13. An electronic device comprising:
the semiconductor device according to claim 1;
an O-ring surrounding the tube in plan view and including an inner circumferential portion in contact with the outer side surface of the body portion of the tube; and
a housing to which the semiconductor device is attached.

14. The electronic device according to claim 13, wherein
the housing includes a recessed portion that is recessed from an inner surface of the housing towards an outer surface of the housing and in which at least the tube and the O-ring of the semiconductor device are located and a cavity through which the recessed portion is open to an outside of the housing and that exposes the detector of the detector assembly to the outside of the housing through the tube disposed in the recessed portion; and
an inner side surface of the housing includes, in an end portion adjacent to the inner surface of the housing, a tapered surface with an inner diameter that decreases toward the outer surface of the housing from the inner surface of the housing, the inner side surface defining the recessed portion.

15. The electronic device according to claim 13, wherein the base portion of the resin package is polygonal in plan view, and the flange portion of the tube is circular or substantially circular in plan view.

16. The electronic device according to claim 15, wherein the base portion of the resin package includes a first base portion on the upper surface of the base substrate and a second base portion projecting from the first base portion, is located inside an outer edge portion of the first base portion in plan view, and supports the flange portion of the tube.

17. The electronic device according to claim 16, wherein the first base portion of the resin package is polygonal in plan view, and the second base portion of the resin package is circular or substantially circular in plan view.

18. The electronic device according to claim 13, wherein the resin package is located inside an outer edge portion of the base substrate in plan view.

19. The electronic device according to claim 18, wherein the base substrate is polygonal in plan view, and the resin package is circular or substantially circular in plan view.

20. The electronic device according to claim 13, wherein the body portion of the tube is cylindrical or elliptic-cylindrical.
